(19) United States
(12) Patent Application Publication
(10) Pub. No.: US 2012/0256322 A1
(43) Pub. Date: Oct. 11, 2012

(54) SEMICONDUCTOR DEVICE

(75) Inventors: Fumito Itou, Osaka (JP); Hiroshige Hirano, Niigata (JP); Yukitoshi Ota, Osaka (JP)

(73) Assignee: PANASONIC CORPORATION, Osaka (JP)

(21) Appl. No.: 13/495,861

(22) Filed: Jun. 13, 2012

Related U.S. Application Data
(63) Continuation of application No. PCT/JP2010/005132, filed on Aug. 19, 2010.

(30) Foreign Application Priority Data
Jan. 14, 2010 (JP) 2010-005937

(51) Int. Cl. H01L 25/07

(52) U.S. Cl. 257/778; 257/E25.016

(57) ABSTRACT

A semiconductor device includes a first semiconductor chip provided with a first semiconductor element including a plurality of element electrodes; and a first substrate having an element mounting surface on which the first semiconductor chip is mounted. The first substrate includes a plurality of first electrodes, each formed on the element mounting surface; a plurality of first interconnects connected to the first electrodes; a plurality of second electrodes formed on a surface opposite to the element mounting surface; a plurality of second interconnects connected to the second electrodes; a plurality of through-hole interconnects penetrating the first substrate and connecting the first interconnects to the second interconnects; and a third semiconductor element. The first side of the first substrate is shorter than the first side of the first semiconductor chip.

### CROSS-REFERENCE TO RELATED APPLICATION

This is a continuation of PCT International Application PCT/JP2010/005132 filed on Aug. 19, 2010, which claims priority to Japanese Patent Application No. 2010-005937 filed on Jan. 14, 2010. The disclosures of these applications including the specifications, the drawings, and the claims are hereby incorporated by reference in their entirety.

### BACKGROUND

The present disclosure relates to semiconductor devices and fabrication methods of the devices, and more particularly to semiconductor devices formed by packaging miniaturized semiconductor elements and fabrication methods of the devices.

In recent years, in order to satisfy the demand for higher performance of semiconductor elements and for transmission to high-speed memories etc. around the semiconductor elements, a high-function system-in-package including a plurality of semiconductor elements mounted in a single package is increasingly demanded.

Conventionally, in a semiconductor device including a plurality of semiconductor elements mounted in a single package, a plurality of semiconductor elements are flip-chip mounted on an intermediate substrate. The intermediate substrate, on which the semiconductor elements are mounted, are connected to a principal wiring substrate such as a ball grid array (BGA), using wires (see, for example, Japanese Patent Publication No. 2008-244104).

### SUMMARY

In a conventional semiconductor device, however, wires are used for connecting an intermediate substrate to a principal wiring substrate. This structure requires an area for connecting the intermediate substrate to the wires, which causes difficulty in reducing the size of the intermediate substrate.

It is an objective of the present disclosure to provide a low-cost semiconductor device including an intermediate substrate in a reduced size.

In order to achieve the objective, the present disclosure provides a semiconductor device, in which semiconductor chips are mounted on a substrate having through-hole interconnects, and electrodes formed on the back surface of the substrate are connected to the semiconductor chips by the through-hole interconnects.

Specifically, an example semiconductor device includes a first semiconductor chip provided with a first semiconductor element including a plurality of element electrodes; and a first substrate having an element mounting surface on which the first semiconductor chip is mounted. The first substrate includes a plurality of first electrodes, each formed on the element mounting surface and connected to one of the element electrodes, a plurality of first interconnects connected to the first electrodes, a plurality of second electrodes formed on a surface opposite to the element mounting surface, a plurality of second interconnects connected to the second electrodes, a plurality of through-hole interconnects penetrating the first substrate and connecting the first interconnects to the second interconnects, and a third semiconductor element. The first substrate and the first semiconductor chip are in a rectangular planar shape. A first side of the first substrate and a first side of the first semiconductor chip are arranged in a same direction. The first side of the first substrate is shorter than the first side of the first semiconductor chip.

As such, in the example semiconductor device, the first substrate includes a plurality of through-hole interconnects connecting the first interconnects to the second interconnects. Thus, the element electrodes are connected to the second electrodes via the first electrodes, the first interconnects, the through-hole interconnects, and the second interconnects. This enables external connection of the semiconductor device via the second electrodes formed on the back surface of the first substrate. As a result, there is no need to provide an area for wire bonding on the element mounting surface of the first substrate, thereby reducing the area of the first substrate. Furthermore, since the one side of the first substrate is shorter than the side of the first semiconductor chip, which is arranged in the same direction, the area of the first substrate can be further reduced.

In the example semiconductor device, the first substrate may have a linear expansion coefficient of 10 ppm/° C. or less.

The example semiconductor device may further include a second substrate including a plurality of substrate connecting electrodes on a substrate mounting surface. The first substrate may be formed above the substrate mounting surface of the second substrate. The second electrodes are connected to the substrate connecting electrodes via raised electrodes.

In the example semiconductor device, the first semiconductor chip may be flip-chip mounted.

The example semiconductor device may further include a second semiconductor chip provided with a second semiconductor element including a plurality of element electrodes. The second semiconductor chip may be flip-chip mounted on the element mounting surface.

In the example semiconductor device, a difference between a height from the first substrate to an upper surface of the first semiconductor chip, and a height from the first substrate to an upper surface of the second semiconductor chip may be 20 μm or less.

In the example semiconductor device, the first electrodes may be formed at smaller pitches than the second electrodes.

In the example semiconductor device, a minimum interconnection width of the first interconnects may be smaller than a minimum interconnection width of the second interconnects.

In the example semiconductor device, the first substrate has a smaller thickness than the first semiconductor chip.

An example fabrication method of a semiconductor device includes the steps of: (a) forming a plurality of first electrodes and a plurality of first interconnects connected to the first electrodes on an element mounting surface of a substrate; (b) forming a plurality of openings in the substrate from a back surface of the substrate, and forming, in the openings, through-hole interconnects connected to the first interconnects; (c) forming a plurality of second electrodes and a plurality of second interconnects connected to the second electrodes on the back surface; (d) after the step (c), mounting a semiconductor chip including a plurality of element electrodes on the element mounting surface so that the element electrodes are connected to the first electrodes; and (e) applying resin to a gap between the semiconductor chip and the substrate with the semiconductor chip facing downward. A first side of the substrate and a first side of the semiconductor chip are arranged in a same direction. The first side of the substrate is shorter than the first side of the semiconductor chip.

In the example fabrication method of the semiconductor device, the resin is applied with the semiconductor chip facing downward. Therefore, the resin stably fills the gap even when the first side of the substrate is shorter than the first side of the semiconductor chip.

According to the semiconductor device and a fabrication method of the device of the present disclosure, a low-cost semiconductor device including an intermediate substrate in a reduced size can be provided.

### BRIEF DESCRIPTION OF THE DRAWINGS

FIGS. 1A and 1B illustrate a semiconductor device according to an embodiment.

FIG. 1A is a top view. FIG. 1B is a cross-sectional view taken along the line Ib-Ib of FIG. 1A.

FIG. 2A is a top view illustrating an arrangement of first electrodes above a first substrate. FIG. 2B is a top view illustrating an arrangement of second electrodes above the first substrate.

FIG. 3A-3C are cross-sectional views illustrating a method of manufacturing the semiconductor device according to the embodiment in order of steps.

FIGS. 4A and 4B are cross-sectional views illustrating the method of manufacturing the semiconductor device according to the embodiment in order of steps.

### DETAILED DESCRIPTION

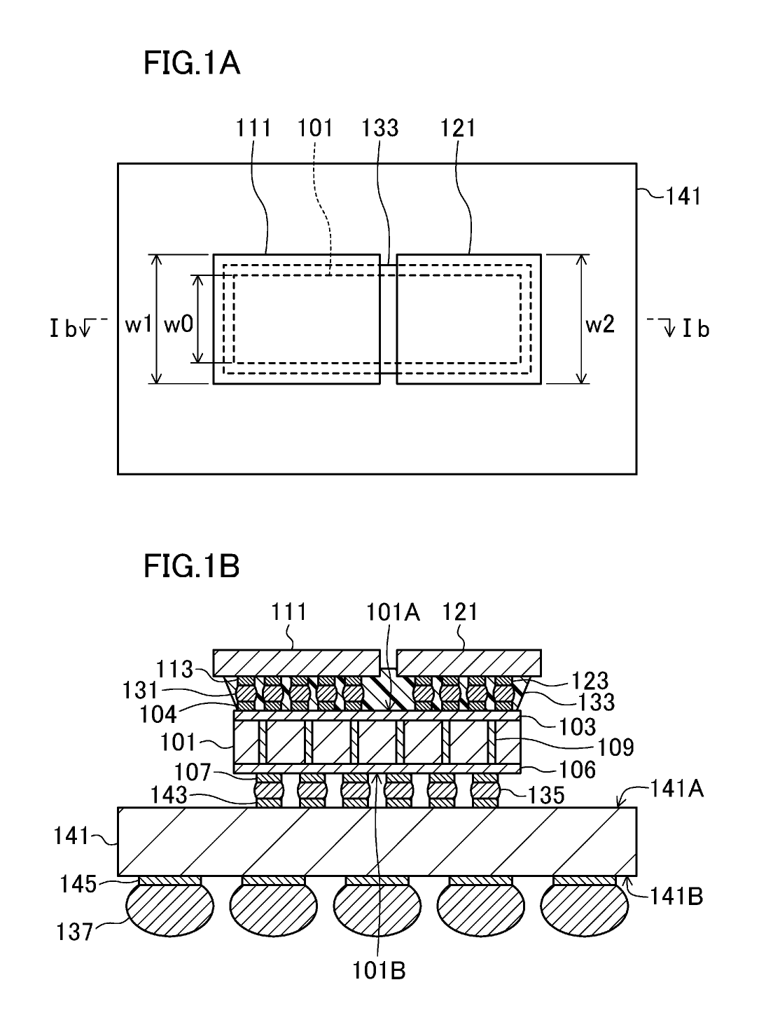

FIGS. 1A and 1B illustrate a semiconductor device according to an embodiment. FIG. 1A illustrates the structure viewed from above. FIG. 1B illustrates the cross-sectional structure taken along the line Ib-Ib of FIG. 1A. As shown in FIGS. 1A and 1B, a first semiconductor chip 111 and a second semiconductor chip 121 are flip-chip mounted on an element mounting surface 101A of a first substrate 101, which is an intermediate substrate. The first semiconductor chip 111 is a semiconductor substrate which includes a first semiconductor element (not shown) formed thereon and a plurality of the first element electrodes 113 on one surface. The second semiconductor chip 121 is a semiconductor substrate which includes a second semiconductor element (not shown) formed thereon, and a plurality of second element electrodes 123 on one surface.

A first interconnect layer 103 including a plurality of first interconnects (not shown), and a plurality of first electrodes 104 connected to the first interconnects are formed on the element mounting surface 101A of the first substrate 101. The first electrodes 104 are connected to the respective first element electrodes 113 or the respective second element electrodes 123 via bumps 131. Resin 133 fills the gap between the element mounting surface 101A and the first and second semiconductor chips 111 and 121.

In this embodiment, as shown in FIGS. 1A and 1B, the width w0 of the first substrate 101 is smaller than the width w1 of the first semiconductor chip 111 and the width w2 of the second semiconductor chip 121. Specifically, the short side of the first substrate 101 is shorter than the side of the first semiconductor chip 111 along the short side of the first substrate 101. This structure further miniaturizes the semiconductor device. Furthermore, the costs for the first substrate 101 can be reduced. In FIGS. 1A and 1B, an example has been described where the width w1 of the first semiconductor chip 111 is substantially equal to the width w2 of the second semiconductor chip. However, the width w1 of the first semiconductor chip 111 may differ from the width w2 of the second semiconductor chip. Alternatively, only one of the width w1 of the first semiconductor chip 111 and the width w2 of the second semiconductor chip may be greater than the width w0 of the first substrate 101.

A second interconnect layer 106 including a plurality of second interconnects (not shown), and a plurality of second electrodes 107 connected to the second interconnects are formed on the surface (back surface) 101B of the first substrate 101, which is opposite to the element mounting surface 101A. The first interconnects are connected to the second interconnects via through-hole interconnects 109 penetrating the first substrate 101.

The second electrodes 107 are connected to second bumps 135 which are raised electrodes. The second bumps 135 are connected to substrate connecting electrodes 143 formed on a substrate mounting surface 141A of a second substrate 141 which is a resin substrate etc. External connecting electrodes 145 are formed on an external connecting electrode formation surface 141B of the second substrate 141, which is opposite to the substrate mounting surface 141A. The substrate connecting electrodes 143 are connected to the external connecting electrodes 145 by interconnects (not shown) formed in the second substrate 141. The interconnects include, for example, interconnects formed in the substrate mounting surface 141A, interconnects formed in the external connecting electrode formation surface 141B, and interconnects penetrating the second substrate 141. Note that the second substrate 141 may be a mother board including what is called sets without providing the external connecting electrodes 145.

With this structure, the first element electrodes 113 and the second element electrodes 123 are connected to the second electrodes 107, which is provided on the back surface 101B of the first substrate 101, via the bumps 131, the first electrodes 104, the first interconnects, the through-hole interconnects 109, and the second interconnects. The first element electrodes 113 and the second element electrodes 123 are connected to the substrate connecting electrodes 143 of the second substrate 141 via the second bumps 135. Depending on the structure of the second substrate 141, the first element electrodes 113 and the second element electrodes 123 are connected to the external connecting electrodes 145, which are formed on the surface opposite to the substrate mounting surface 141A via the through-hole interconnect etc. This extracts the electrodes of the semiconductor chips outside the semiconductor device without using wires. Therefore, there is no need to provide an area for wiring connection in the first substrate 101, thereby miniaturizing the semiconductor device. With the reduction in the area of the substrate 101, manufacturing costs can be reduced.

The first substrate 101 may be a wiring substrate such as a printed-circuit board. Alternatively, the first substrate 101 may be a silicon substrate etc. so as to form high-density interconnection. The first substrate 101 may be used as a semiconductor chip provided with a third semiconductor element (not shown) to form a stacked chip package. The first substrate 101 may be provided with an input/output circuit, global wiring, etc. The linear expansion coefficient of the first substrate 101 may be substantially equal to that of the first semiconductor chip 111. Thus, the linear expansion coefficient of the first substrate 101, which is the linear expansion coefficient of silicon, is preferably 10 ppm/° C. or less. For example, the first substrate 101 may be a glass substrate etc.

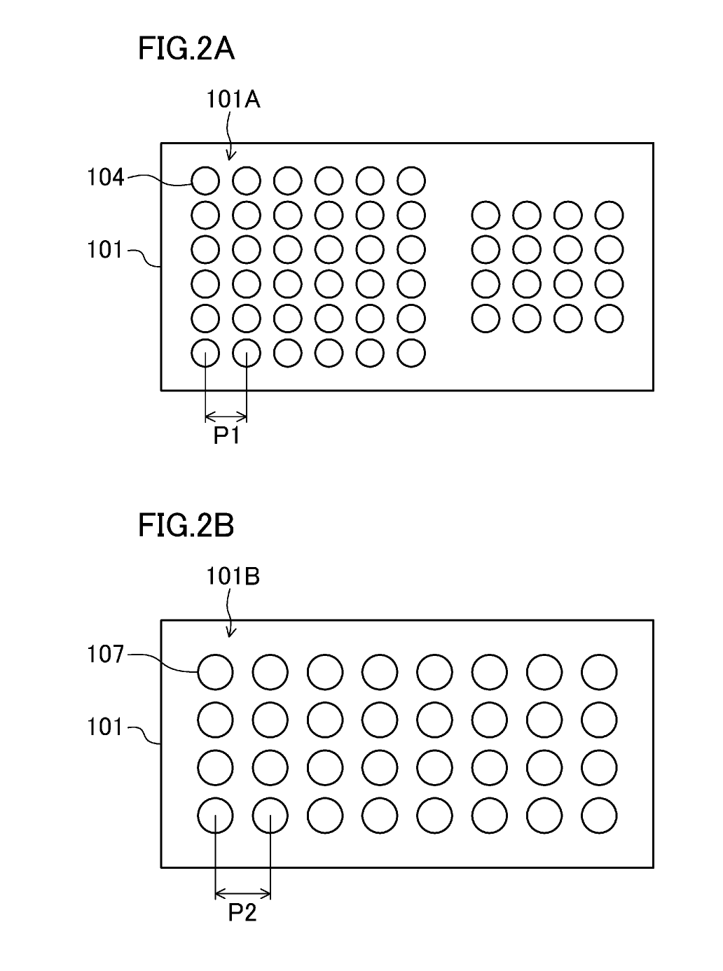

FIGS. 2A and 2B illustrate an arrangement of the first electrodes 104 formed on the element mounting surface 101A, and an arrangement of the second electrodes 107 formed on the back surface 101B, respectively. As shown in FIGS. 2A and 2B, the minimum pitch P1 between the first electrodes 104 is preferably smaller than the minimum pitch P2 between the second electrodes 107. The minimum line width of the first interconnects is preferably smaller than the minimum line width of the second interconnects. This structure reduces the interconnection density on the first substrate 101.

The first semiconductor chip 111 and the second semiconductor chip 121 may be any semiconductor chip. For example, the first semiconductor chip 111 may be a system LSI, and the second semiconductor chip may be a memory device such as a dynamic random access memory of number of bits. Alternatively, various semiconductor chips such as a system LSI, an analog LSI, a high frequency LSI, etc. may be combined. The semiconductor elements and the element electrodes may be formed on different surfaces of the semiconductor chip. However, they are preferably formed on the same surface, since there is no need to form through-hole interconnects penetrating the semiconductor chips.

The difference between the height from the first substrate 101 to the upper surface of the first semiconductor chip 111, and the height from the first substrate 101 to the upper surface of the second semiconductor chip 121 is preferably 20 μm or less in view of handling characteristics, attachment of a heat release jig, etc. On the other hand, the first substrate 101 is preferably thinner than the first semiconductor chip 111 and the second semiconductor chip 121 to facilitate the formation of the through-hole interconnects 109. For example, the first semiconductor chip 111 and the second semiconductor chip 121 may have a thickness ranging from 200 μm to 800 μm, and the first substrate 101 may have a thinner thickness ranging from about 50 μm to 250 μm.

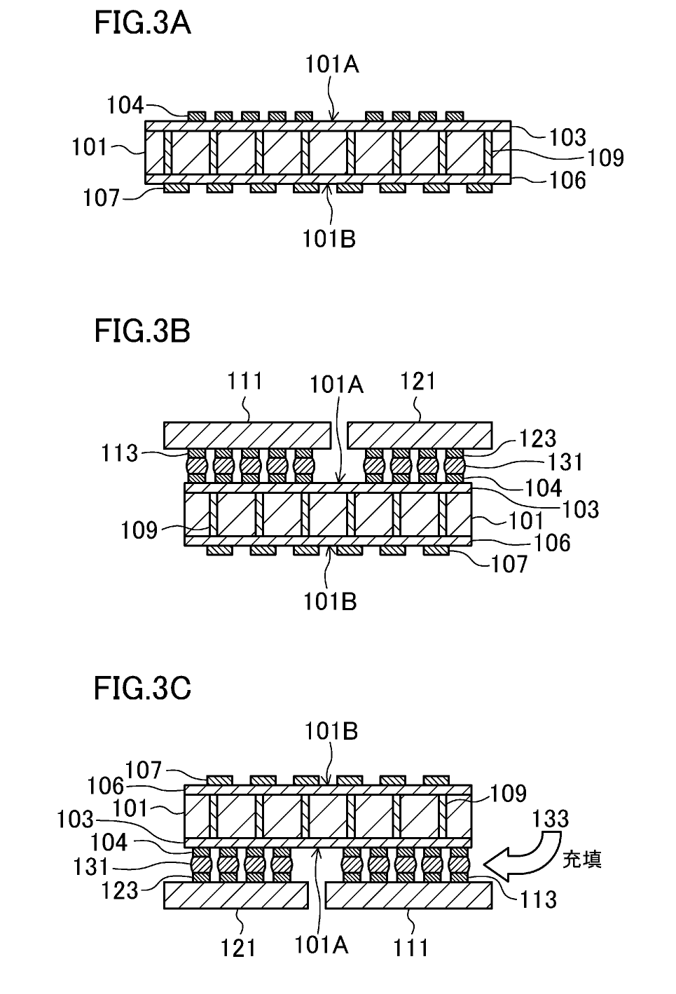

FIGS. 3A-3C illustrate a method of manufacturing the semiconductor device according to this embodiment in order of steps. First, as shown in FIG. 3A, the first electrodes 104 and the first interconnect layer 103, which includes first interconnects connected to the first electrodes 104, are formed on the element mounting surface 101A of the first substrate 101. Next, through-holes penetrating the first substrate 101 from the back surface 101B to the element mounting surface 101A are formed, and then, a conductive material fills the through-holes, thereby forming the through-hole interconnects 109 which are connected to the first interconnects. After that, the second interconnect layer 106, which includes second interconnects connected to the through-hole interconnects 109, and the second electrodes 107 connected to the second interconnects are formed on the back surface.

Then, as shown in FIG. 3B, the first semiconductor chip 111 including the first element electrodes 113, and the second semiconductor chip 121 including the second element electrodes 123 are flip-chip mounted on the element mounting surface 101A of the first substrate 101. The flip-chip mounting may be performed by fusion junction using solder for the bumps 131. Alternatively, the bumps 131 may be stud bumps or plated bumps and the flip-chip mounting may be performed by a method using an anisotropic conductive film (ACF) or a nonconductive film (NCF).

Next, as shown in FIG. 3C, the resin 133 fills the connection gap between the element mounting surface 101A and the first and second semiconductor chip 111 and 121. The filling of the resin 133 is performed with the element mounting surface 101A facing downward. With this structure, the resin 133 stably fills the gap even when the first substrate 101 has a smaller width than the first semiconductor chip 111.

Note that the distance between the element mounting surface 101A and the surfaces of the first and second semiconductor chips 111 and 121, on which the first and second element electrodes 113 and 123 are respectively formed, is preferably 20 μm or less.

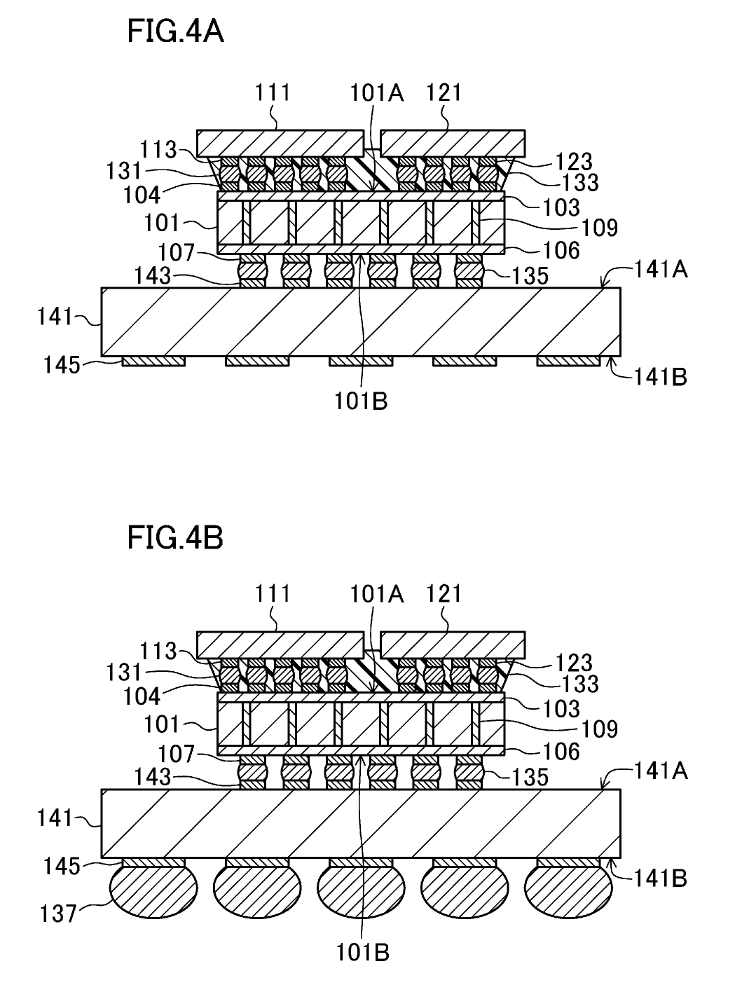

After that, as shown in FIG. 4A, the second electrodes 107 of the first substrate 101 are connected to the substrate connecting electrodes 143 of the second substrate 141 by the second bumps 135.

Then, as shown in FIG. 4B, third bumps 137, which are raised electrodes for external connection, are mounted on the external connecting electrodes 145 of the second substrate 141.

The materials and numerical values shown in this embodiment are merely preferable examples, and it is not intended to limit the scope of the present disclosure. Various modifications may be made within the spirit and scope of the present invention.

The semiconductor device and a fabrication method of the device according to the present disclosure provides a low-cost semiconductor device including an intermediate substrate in a reduced size, and is useful for a semiconductor device formed by packaging miniaturized semiconductor elements etc.

What is claimed is:

1. A semiconductor device comprising:
a first semiconductor chip provided with a first semiconductor element including a plurality of element electrodes; and
a first substrate having an element mounting surface on which the first semiconductor chip is mounted, wherein
the first substrate includes
a plurality of first electrodes, each formed on the element mounting surface and connected to one of the element electrodes,
a plurality of first interconnects connected to the first electrodes,
a plurality of second electrodes formed on a surface opposite to the element mounting surface,
a plurality of second interconnects connected to the second electrodes,
a plurality of through-hole interconnects penetrating the first substrate and connecting the first interconnects to the second interconnects, and
a third semiconductor element,
the first substrate and the first semiconductor chip are in a rectangular planar shape,
a first side of the first substrate and a first side of the first semiconductor chip are arranged in a same direction, and
the first side of the first substrate is shorter than the first side of the first semiconductor chip.

2. The semiconductor device of claim 1, wherein
the first substrate has a linear expansion coefficient of 10 ppm/° C. or less.

3. The semiconductor device of claim 1, further comprising
a second substrate including a plurality of substrate connecting electrodes on a substrate mounting surface, wherein
the first substrate is formed above the substrate mounting surface of the second substrate, and
the second electrodes are connected to the substrate connecting electrodes via raised electrodes.

4. The semiconductor device of claim 1, wherein
the first semiconductor chip is flip-chip mounted.

5. The semiconductor device of claim 1, further comprising
a second semiconductor chip provided with a second semiconductor element including a plurality of element electrodes, wherein
the second semiconductor chip is flip-chip mounted on the element mounting surface.

6. The semiconductor device of claim 5, wherein
a difference between a height from the first substrate to an upper surface of the first semiconductor chip, and a height from the first substrate to an upper surface of the second semiconductor chip is 20 μm or less.

7. The semiconductor device of claim 1, wherein
the first electrodes are formed at smaller pitches than the second electrodes.

8. The semiconductor device of claim 1, wherein
a minimum interconnection width of the first interconnects is smaller than a minimum interconnection width of the second interconnects.

9. The semiconductor device of claim 1, wherein
the first substrate has a smaller thickness than the first semiconductor chip.
